(19) United States
(12) Patent Application Publication
(10) Pub. No.: US 2005/0110397 A1
(43) Pub. Date: May 26, 2005

(54) Film forming method, device manufacturing method, and electro-optic device

(75) Inventor: Takashi Masuda, Suwa-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/935,242

(22) Filed: Sep. 8, 2004

(30) Foreign Application Priority Data
Sep. 25, 2003 (JP) 2003-333357(P)

(51) Int. Cl. B32B 5/02; B05D 3/02; H05B 33/10

(52) U.S. Cl. 313/504; 427/258; 427/427.1; 427/372.2; 445/24

(57) ABSTRACT

Aspects of the invention can provide a film forming method capable of forming a extremely fine film pattern easily. The film forming method can include a liquid discharging step in which a first droplet is discharged on a substrate, a pinning step in which a first dry film is formed in a peripheral part of the first droplet, a redispersion step in which a second droplet is arranged so as to include a part of first dry film and the part of the first dry film is redispersed, and a repinning step in which a second dry film is formed in a peripheral part of the second droplet.

### BACKGROUND OF THE INVENTION

1. Field of Invention

Aspects of the invention can relate to a film forming method, a device manufacturing method, and an electro-optic device.

2. Description of Related Art

Related patterning methods using an ink-jet method, as described in, for example, U.S. Pat. No. 5,132,248, can include a method in which a liquid material with fine particles being dispersed are directly applied to a substrate in a pattern by the ink-jet method, and thereafter heat treatment and laser irradiation are performed to convert into a conductive film pattern. According to this method, pattern formation can be performed without using a photolithography technology, and thus the pattern formation process can be simplified.

Furthermore, as a related patterning method using the ink-jet method, as disclosed in, for example, Japanese Unexamined Patent Publication No. S59-75205, there is a method in which a bank is provided on a substrate so as to control a position of a discharged droplet, thereby improving pattern formation precision. The formation of the bank prevents the droplet discharged on the substrate from running off outside of the bank and, for example, enables a pattern of about 30 μm with a position precision of about 1 μm to be formed.

In addition to the above-mentioned related patterning methods, a method in which a liquid material is selectively applied only to a lyophilic part of a substrate having a pattern of a liquid repellent part and the lyophilic part formed of an organic molecular film, and thereafter the heat treatment converts into a conductive pattern can be utilized. In this case, the conductive pattern can be formed by a simple process at high precision.

### SUMMARY OF THE INVENTION

With recent miniaturization of devices, a finer pattern has been demanded. In a related patterning method using the ink-jet method, a formed line width depends on a size of a discharged droplet, so that the droplet size needs to be small in order to form the line width thin. However, there has been a problem that there is a limit to reduce the droplet size due to a structural problem of a droplet discharging device or the like.

In an aspect of the invention, a finer pattern than the droplet size can be formed by collecting solid contents contained in the droplet in a peripheral part of the droplet using convection inside of the droplet. In this technology, the droplet is arranged in stripe and in the peripheral part thereof, a dry film is formed to thereby form two patterns along a longitudinal direction in the stripe. Thereby, the pattern can be miniaturized as compared with the conventional patterning method. In view of application to a device, however, there have remained a few problems that two patterns are always formed and an interval between the respective patterns depends on the droplet size, or the like.

Aspects of the invention can provide a film forming method and a device manufacturing method capable of forming an extremely fine film pattern easily.

Another aspect can provide a small-size electro-optic device having excellent display quality by including the extremely fine film pattern.

A film forming method of the invention can include arranging a first droplet on a substrate, forming a first dry film in a peripheral part of the first droplet, and removing a part of the first dry film and forming a desired film pattern by a remaining part of the first dry film. According to this structure, since the first dry film is formed in the peripheral part of the first droplet, even if the first droplet has a limit in size, the fine film pattern can be formed by the first droplet. Furthermore, by removing the part of the first dry film, the desired film pattern can be easily formed.

Furthermore, another exemplary film forming method of the invention can include arranging a first droplet on a substrate, forming a first dry film in a peripheral part of the first droplet, arranging a second droplet so as to include a part of the first dry film and redispersing or redissolving the part of the first dry film, and removing the second droplet and forming a desired film pattern by a remaining part of the first dry film. According to this structure, since the part of the first dry film is redispersed or redissolved to be removed, the part can be removed precisely and easily. Accordingly, the extremely fine film pattern can be easily formed.

Furthermore, another exemplary film forming method of the invention can include arranging a first droplet on a substrate, forming a first dry film in a peripheral part of the first droplet, arranging a second droplet so as to include a part of the first dry film and redispersing or redissolving the part of the first dry film, and forming a second dry film in a peripheral part of the second droplet. According to this structure, since the part of the first dry film is redispersed or redissolved by the second droplet and the second dry film is formed in the peripheral part of the second droplet, the first dry film and the second dry film can be arranged adjacently to each other. Accordingly, the extremely fine film pattern can be easily formed. Furthermore, it is desirable that after forming the first dry film, a region corresponding to the remaining part of the first dry film is heat-treated.

In the heat-treated part, adhesion between a component material of the first dry film and the substrate becomes strong and thus the component material of the first dry film is neither redispersed nor redissolved. Accordingly, the remaining part of the first dry film can be shaped precisely, and the extremely fine film pattern can be easily formed.

Furthermore, it is desirable that before forming the first dry film, the component material of the first dry film and the substrate are charged to the same charge. According to this structure, since the adhesion between the component material of the first dry film and the substrate becomes weak, the first dry film can be efficiently redispersed and redissolved. Furthermore, it is desirable that the second droplet is composed of only a dispersion medium or a solvent of the component material of the first dry film.

In the case where the second dry film is not formed, a component material of the second dry film is not contained in the second droplet, but the second droplet can be composed of only the dispersion medium or the solvent. Thereby, the second droplet can be produced easily and at low cost.

Furthermore, it is desirable that a concentration of the component material of the second dry film in the second droplet is set so as to be a desired concentration in a state that the part of the first dry film is redispersed or redissolved. According to this structure, the second dry film having a desired shape can be formed, and thus the extremely fine film pattern can be formed.

Meanwhile, in an exemplary device manufacturing method of the invention, using the above-mentioned film forming methods, a film pattern is formed on the substrate. According to this structure, a device comprising the extremely fine film pattern can be manufactured.

Meanwhile, in an exemplary device manufacturing method of the invention, using the above-mentioned film forming methods, electric wiring is formed on the substrate. According to this structure, a device comprising the extremely fine electric wiring can be manufactured, to thereby miniaturize the device.

Meanwhile, an electro-optic device of the invention comprises a device manufactured using the above-mentioned device manufacturing methods. According to this structure, by comprising the extremely fine film pattern or the electric wiring, the small-size electro-optic device with excellent display quality can be provided.

### BRIEF DESCRIPTION OF THE DRAWINGS

The invention will be described with reference to the accompanying drawings, wherein like numerals reference like elements, and wherein:

FIGS. 1A-1D are explanatory views of a film forming method of a first exemplary embodiment;

FIGS. 2A-2B are views schematically showing a typical drying step of a droplet;

FIG. 3 is a perspective view of a droplet discharging device;

FIG. 4 is a side cross-sectional view of an ink jet head;

FIGS. 5A-5D are explanatory views of a film forming method of a second exemplary embodiment;

FIGS. 6A-6D are explanatory views of a film forming method of a third exemplary embodiment;

FIG. 7 is a side cross-sectional view of an organic EL device; and

FIG. 8 is a perspective view of a cellular phone.

### DETAILED DESCRIPTION OF PREFERRED EMBODIMENTS

Hereinafter, the embodiments of the present invention are described referring to the drawings. In the respective drawings used for the description below, respective members are changed in scale size as necessary in order to scale the members to recognizable sizes.

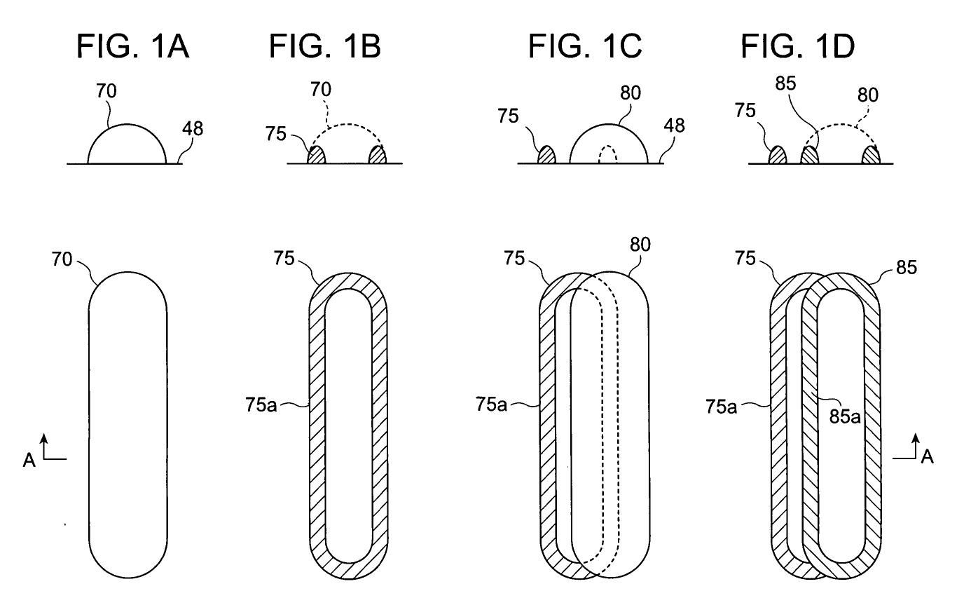

Firstly, a film forming method according to a first exemplary embodiment of the invention is described using FIGS. 1 through 4.

FIG. 1 is an explanatory view of a film forming method of the first embodiment. Lower views of FIGS. 1A through 1D are plan views of a droplet and/or a dry film, and upper views of FIGS. 1A through 1D are side cross-sectional views taken along A-A line in the lower views, respectively. In the film forming method according to the first embodiment, firstly as shown in FIG. 1A, a first droplet 70 is discharged on a substrate 48 (droplet discharging step). Next, as shown in FIG. 1B, in a peripheral part of the first droplet 70, a first dry film 75 is formed (pinning step). Then, as shown in FIG. 1C, on the substrate 48, a second droplet 80 is arranged and a part of the first dry film 75 is redispersed (redispersion step). Next, as shown in FIG. 1D, in a peripheral part of the second droplet 80, a second dry film 85 is formed (repinning step). Thereby, there can be formed an electric wiring pattern in which a linear part 75a of the first dry film 75 and a linear part 85a of the second dry film 85 are arranged adjacently to each other. The respective steps mentioned above are sequentially described below.

Firstly, as shown in FIG. 1A, the first droplet 70 is discharged on the substrate 48 (droplet discharging step). Specifically, a forming material of the first dry film is dispersed in a dispersion medium to produce a liquid material (ink for ink jet), and the liquid material is discharged from a droplet discharging device described later on the substrate so as to form the first droplet 70. In the present embodiment, since the electric wiring pattern is formed by the first dry film, as the forming material of the first dry film, conductive fine particles such as Ag fine particles are employed. Furthermore, as the dispersion medium, an organic dispersion medium such as tetradecan can be employed. On the other hand, the first droplet 70 is formed in stripe. In this case, semispherical micro droplets are arranged at predetermined intervals. Then, the respective micro droplets are wetted and spread to combine with each other between the adjacent micro droplets and form the first droplet 70 in stripe.

Next, as shown in FIG. 1B, in the peripheral part of the first droplet 70, the first dry film 75 is formed (pinning step). Specifically, the first dry film 75 is shaped such that a film thickness of the peripheral part is larger than that of a central part, that is, such that the peripheral part rises. In this example, by controlling drying conditions with respect to the first droplet 70, the shape of the first dry film 75 is controlled.

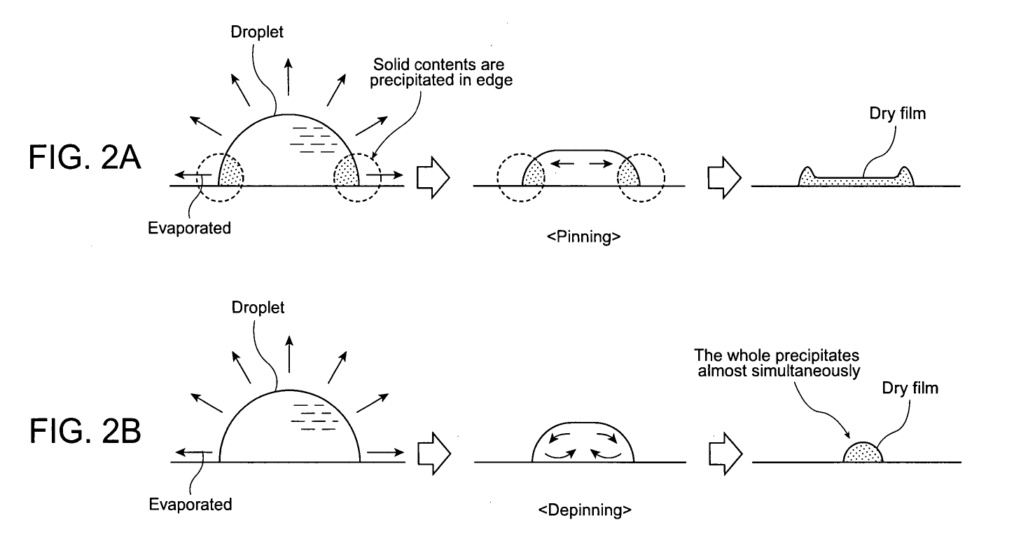

Here, FIG. 2 is a view schematically showing a typical drying step of the droplet.

In the drying step of the droplet, by using a concentration of solid contents of the liquid material, a drying speed of the droplet, a particle diameter in the case where the solid contents are fine particles, or the like as parameters, the dry film of the droplet can be controlled into various shapes. For example, as shown in FIG. 2A, the shape can be such that the film thickness of the peripheral part is larger than that of the central part, or as shown in FIG. 2B, such that the dry film is contracted as compared with the droplet after touching down.

In the drying step as shown in FIG. 2A, the above-mentioned parameters (the concentration of solid contents of the liquid material, the drying speed of the droplet, and the particle diameter of fine particles) are determined so that the concentration of the solid contents in the peripheral part of the droplet reaches a saturated concentration earlier than that of the central part. Generally, with regard to the droplet arranged on the substrate, the drying progresses faster in the peripheral part (edge). In the drying step of the droplet, when the concentration of the solid contents in the peripheral part of the droplet reaches the saturated concentration, the solid contents are locally precipitated in the peripheral part. Then, the precipitated solid contents bring about such a state that the peripheral part of the droplet is pinned, and the contraction (contraction of an outside diameter) of the droplet accompanying the subsequent drying is suppressed. Hereinafter, this phenomenon, that is, the phenomenon in which the contraction of the droplet accompanying the drying is suppressed by the solid contents precipitated in the peripheral part is referred to as pinning.

In the drying step as shown in FIG. 2B, the above-mentioned parameters (the concentration of the solid contents of the liquid material, the drying speed of the droplet, and the particle diameter of the fine particles) are determined so that the concentration of the solid contents of the entire droplet reaches the saturated concentration substantially simultaneously. In this case, since it is hard to generate the local precipitation of the solid contents in the peripheral part of the droplet, the above-mentioned pinning does not occur, and the entire droplet is contracted in the drying step to reduce the droplet in outside diameter. Hereinafter, this phenomenon is referred to as deppining. The flow of the liquid inside of the droplet indicated by arrow in FIGS. 2A and 2B is one example, and thus may be different from actual flow.

When the pinning as shown in FIG. 2A occurs, a flow for compensating for an amount of the liquid lost due to evaporation in the peripheral part of the droplet from the central part, that is, a liquid flow from the central part to the peripheral part is formed. When this flow is formed intensively, much of the solid contents contained in the droplet are conveyed to the peripheral part. In the peripheral part of the droplet, the liquid flow is easily retained due to an increase in viscosity accompanying the precipitation of the solid contents or the like, and thus a state of a high concentration of the solid contents is maintained. In other words, a liquid flow from the peripheral part to the central part is weaker as compared with the liquid flow from the central part to the peripheral part. As a result, much of the solid contents are precipitated in the peripheral part of the droplet, and thus the film thickness in the peripheral part becomes large. In this manner, according to the intensity of the flow from the central part to the peripheral part of the droplet, the film thickness in the peripheral part of the dry film can be made larger.

Furthermore, the intensity of the flow from the central part to the peripheral part of the droplet is changed according to the above-mentioned parameters. In the above-mentioned parameters, as the concentration of the solid contents of the liquid material becomes lower, and as the drying speed becomes higher, the flow from the central part to the peripheral part becomes more intensive. Accordingly, by decreasing the concentration of the solid contents of the liquid material or by increasing the drying speed, a film thickness ratio of the peripheral part with respect to the central part of the dry film can be increased. Furthermore, in the case where the solid contents are fine particles, as the particle diameter becomes smaller, the solid contents are more easily conveyed to the peripheral part by the liquid flow, and thus the film thickness of the central part of the dry film becomes thin more easily. By increasing the film thickness ratio of the peripheral part with respect to the central part of the dry film, the ring-shaped first dry film (annular dry film) 75 as shown in FIG. 1B can be formed.

Here, in the above-mentioned parameters, the drying speed of the droplet is changed according to an interval between the droplets (distance between the droplets) arranged on the substrate, timing of array or arrangement of the plurality of droplets and a moving speed of a stage on which the substrate is mounted, a contact angle of a substrate surface with respect to the liquid material, or the like.

When drying the droplet, vapor given out from a liquid phase to a gas phase is diffused three-dimensionally centering on the droplet to form a vapor diffusion layer. When the plurality of droplets are arranged on the substrate, and one droplet is arranged inside of the vapor diffusion layer of another droplet, a vapor concentration in a surface of the one droplet is increased by influence of the vapor diffusion layer and the drying speed of the one droplet is decreased. Specifically, as the distance between the droplets becomes shorter, and as the overlap of the vapor diffusion layers becomes larger, an evaporating speed of the droplet (drying speed) is decreased and thus drying time becomes longer.

Furthermore, in the case where another droplet is arranged only in a specific direction with respect to one droplet, the influence by the vapor diffusion layer of the another droplet is exerted from the specific direction, the drying speed of the one droplet is decreased only in the specific direction. Accordingly, the array of the droplets changes the drying speed. Furthermore, when time from the arrangement of another droplet to the arrangement of one droplet is long, the influence by the vapor diffusion layer of the another droplet is decreased, so that the drying speed of the droplet is hardly decreased. Accordingly, the timing of the arrangement of the droplets changes the drying speed.

When the stage on which the substrate is mounted moves, the vapor concentration of the gas phase in the vicinity of the droplet is decreased or the like, thereby promoting the drying of the droplet. Accordingly, as the moving speed of the stage becomes higher, the relative moving speed of the droplet with respect to the atmosphere becomes higher and thus the drying speed of the droplet becomes higher.

Taking the foregoing into consideration, the above-mentioned parameters are set so as to form the intensive flow from the central part to the peripheral part of the first droplet 70 as shown in FIG. 1B, and the first droplet 70 is dried. Thereby, in the peripheral part of the first droplet 70, the first dry film 75 is formed. Since the first droplet 70 is formed in stripe, the first dry film 75 is formed into an elliptic shape. Accordingly, by using the linear part 75a thereof, a linear electric wiring pattern can be obtained.

When the droplet size is reduced, the miniaturization of the electric wiring is enabled. However, since there is a limit in a minimum dischargeable liquid amount due to structural problems of the droplet discharging device or the like, there is a limit in reducing the droplet size. For example, the minimum dischargeable liquid amount by the droplet discharging device is about 2 pl, and a droplet diameter corresponding to this liquid amount is about 20 to 30 μm. However, the use of the above-mentioned pinning enables forming the finer electric wiring than the droplet size. The fine electric wiring having a line width of about 0.5 to 1.0 μm, for example, can also be formed.

Next, as shown in FIG. 1C, the second droplet 80 is arranged on the substrate 48 and a part of the first dry film 75 is redispersed (redispersion step). Specifically, the forming material of the second dry film is dispersed in a dispersion medium to produce a liquid material (ink for ink jet), and the liquid material is discharged on the substrate from the droplet discharging device to arrange the second droplet 80. In the present embodiment, the electric wiring pattern is formed by the second dry film, and thus as the forming material of the second dry film, the conductive fine particles, such as Ag fine particles are employed. This forming material of the second dry film may be the same material as a dispersoid of the first droplet or may be the different material. In addition, the dispersion medium of the second droplet may be the same material as the dispersion medium of the first droplet, or may be the different material. However, as the dispersion medium of the second droplet, a material capable of redispersing the first dry film composed of the dispersoid of the first droplet is employed. Specifically, similarly to the dispersion medium of the first droplet, the organic dispersion medium such as tetradecan can be employed.

As described above, in the exemplary embodiment, the one linear part 75a in the first dry film 75 formed into an elliptic shape is used. The second droplet 80 is arranged so as to include a part other than the one linear part 75a in the first dry film 75. For example, the second droplet 80 is formed in stripe so as to include the other linear part in the first dry film 75. In this case, the arrangement of semispherical micro droplets at predetermined intervals allows the second droplet in stripe to be formed. In the repinning step described below, in the peripheral part of the second droplet 80, the second dry film is formed, and arranged at a predetermined interval from the linear part 75a of the first dry film 75. Here, the second droplet 80 is formed so that the peripheral part of the second droplet 80 is arranged at the predetermined interval from the linear part 75a of the first dry film 75.

Such an arrangement of the second droplet 80 allows the first dry film 75 covered with the second droplet 80 to be redispersed in the dispersion medium of the second droplet 80. Here, by taking the following factors into consideration, the first dry film 75 can be efficiently redispersed.

On a surface of the fine particle which is a component material of the first dry film 75, a protective layer composed of an organic substance or the like is provided in order to prevent coagulation between the fine particles. This protective layer remains in the fine particle surface even in a state that the first dry film 75 is shaped from the first droplet. When the first dry film 75 is heat-treated (annealing) to decompose the protective layer, the fine particles are mutually coagulated to calcinate the electric wiring. Here, by arranging the second droplet 80 before the heat treatment of the first dry film 75, the first dry film 75 can be redispersed. Furthermore, as a thickness of the protective layer becomes larger, an effect of preventing the coagulation between the fine particles becomes higher, and thus the fine particles having the thick protective layer are desirably employed. This increases a calcination temperature, however the first dry film 75 can be efficiently redispersed.

Furthermore, even when the first droplet is dry-treated to shape the first dry film 75, there may remain the dispersion medium of the first droplet inside of the first dry film 75. Although this remaining dispersion medium makes the first dry film 75 brittle, the first dry film 75 is heat-treated to remove. Here, before the first dry film 75 is heat-treated, the second droplet 80 is arranged, so that the first dry film 75 can be efficiently redispeised. Furthermore, in the case where the dispersion medium of the first droplet has a high boiling point, an incidence of the remaining dispersion medium is high and thus the dispersion medium having a high boiling point is desirably employed for the first droplet. Although this increases the sintering temperature, the first dry film 75 can be efficiently redispersed.

Furthermore, by charging the component material of the first dry film 75 and the substrate 48 to the same charge, adhesion between both becomes weak and the first dry film 75 can be efficiently redispersed. Generally, since the fine particles as the component material of the first dry film 75 are minus charged, the substrate 48 may be minus charged. In order to charge the substrate 48, the self-assembled monolayer (SAM) is desirably used. As a specific self-assembled monolayer, a silane coupling agent expressed by Rₙ—Si—(O-Et)₄₋ₙ is employed. This ethyl group is adsorbed to the substrate 48 and thus a monomolecular film is formed on the substrate 48. In addition, when a carboxyl group (—COO⁻) is employed for the R section, the surface of the substrate 48 can be minus charged. In the case where the fine particles is plus charged, by employing an amino group (—NH₃⁺) for the R section, the substrate surface may be plus charged.

According to the exemplary embodiment, as shown in FIG. 1C, the one linear part 75a in the first dry film 75 formed into an elliptic shape is used to form the electric wiring pattern. Then, the second droplet 80 is arranged in the part other than the linear part 75a. However, in the case where the position of the second droplet 80 is deviated, or in the case where the second droplet 80 is largely wetted and spread, or the like, the second droplet 80 comes into contact with the linear part 75a of the first dry film 75 and the linear part 75a may be redispersed. Therefore, before arranging the second droplet 80, the linear part 75a to be used is desirably heat-treated. In order to precisely subject only the linear part 75a to the heat treatment, the heat treatment is desirably performed by laser irradiation or the like. Thus, the protective layer of the fine particle surface in the linear part 75a is decomposed, so that the fine particles coagulate and the electric wiring is sintered. Furthermore, the remaining dispersion medium in the linear part 75a is removed. Thereby, even when the second droplet 80 comes into contact with the linear part 75a, the linear part 75a can be prevented from being redispersed.

As described above, as shown in FIG. 1C, the second droplet 80 is arranged on the substrate 48 and a part of the first dry film 75 is redispersed.

Next, as shown in FIG. 1D, in the peripheral part of the second droplet 80, the second dry film 85 is formed (repinning step). A specific method thereof is the same as the method for forming the first dry film 75 in the pinning step.

By the way, in the above-mentioned redispersion step, a part of the first dry film 75 is redispersed in the second droplet. Therefore, a concentration of the second droplet after redispersion becomes higher than a concentration of the second droplet before discharging on the substrate. In this case, a formed line width of the second dry film 85 may be larger than a line width of the first dry film 75. Therefore, the concentration of the second droplet before discharging on the substrate is desirably set so as to be a desired concentration in a state that the first dry film 75 is redispersed in the second droplet. In particular, in order to form the first dry film 75 and the second dry film 85 similarly in line width, the concentration of the second droplet before discharging may be set so that the concentration of the second droplet in the state that a part of the first dry film is redispersed is equivalent to the concentration of the first droplet.

As described above, as shown in FIG. 1D, the fine electric wiring pattern composed of the linear part 75a of the first dry film 75 and the linear part 85a of the second dry film 85 is formed. In particular, in the exemplary embodiment, since a part of the first dry film 75 is redispersed in the second droplet and the second dry film 85 is formed in the peripheral part of the second droplet, the linear part 75a of the first dry film 75 and the linear part 85a of the second dry film 85 can be arranged adjacently. This enables the electric wiring pattern with a narrow pitch to be formed. According to this, a device having the electric wiring pattern can be miniaturized.

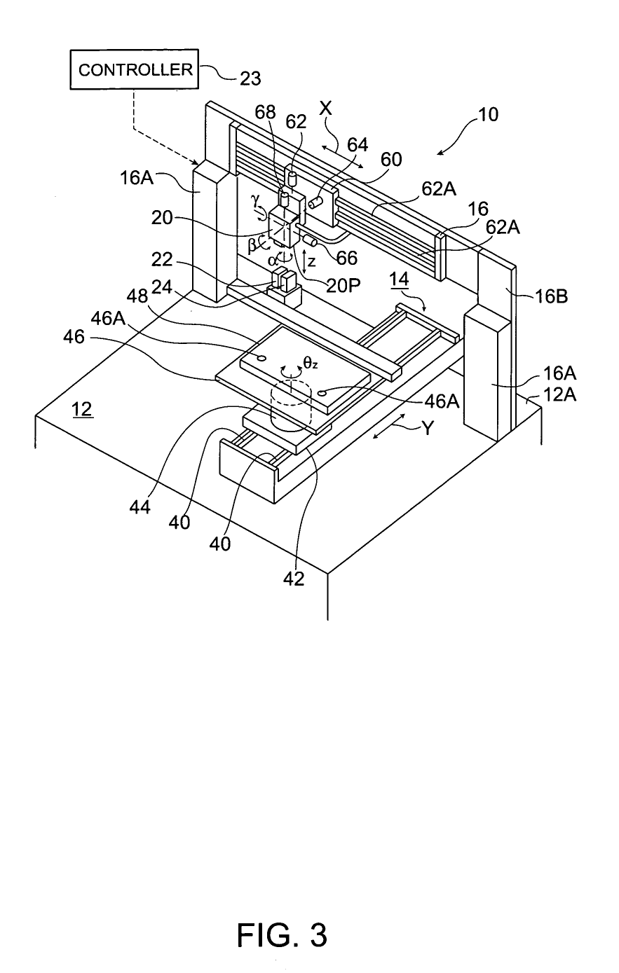

The liquid materials composing the first droplet and the second droplet described above are discharged by the droplet discharging device. FIG. 3 is a perspective view of the droplet discharging device. The droplet discharging device 10 mainly includes a base 12, a first moving device 14, a second moving device 16, an electronic force balance (not shown) as weight measuring means, a head 20, a capping unit 22, and a cleaning unit 24. Operations of the droplet discharging device 10 including the first moving device 14 and the second moving device 16 are controlled by a control device 23. In FIG. 3, an X direction is a horizontal direction of the base 12, a Y direction is a cross direction, and a Z direction is a vertical direction.

The first moving device 14 is set up directly on an upper surface of the base 12 with guide rails 40 and 40 brought in line with the Y axial direction. This first moving device 14 has a slider 42 movable along the guide rails 40 and 40. As a driving device of this slider 42, a linear motor, for example, can be employed. Thereby, the slider 42 can be moved along the Y axial direction and positioning at an arbitrary position can be performed.

On an upper surface of the slider 42, a motor 44 is fixed, and to a rotor of the motor 44, a table 46 is fixed. This table 46 positions the substrate 48 while holding it. Specifically, an adsorption holding device not shown is actuated to adsorb the substrate 48 through a hole 46A of the table 46 and the substrate 48 can be held on the table 46. Furthermore, the motor 44 is a direct drive motor, for example. By energizing this motor 44, the table 46 rotates in a θz direction together with the rotor and the table 46 can be indexed (rotation indexed). In the table 46, there is a preliminary discharging area for the head 20 to perform waste discharging of the liquid material or to perform trial discharging (preliminary discharging).

On the other hand, in rear parts of the base 12, brace members 16A and 16A are set up upright, and at upper end parts of the brace members 16A and 16A, a column 16B is installed. On a front surface of the column 16B, the second moving device 16 is provided. This second moving device 16 has guide rails 62A and 62A arranged along the X axial direction, and a slider 60 movable along the guide rails 62A and 62A. As a driving device of this slider 60, a linear motor, for example, can be employed. Thereby, the slider 60 can be moved along the X axial direction and the positioning at an arbitrary position can be performed.

The slider 60 is provided with the head 20. The head 20 can be connected to the motors 62, 64, 66 and 68 as oscillation positioning means. The motor 62 enables the head 20 to move in the Z axial direction and to be positioned at an arbitrary position. The motor 64 enables the head 20 to be oscillated in a β direction around the Y axis and to be positioned at an arbitrary position. The motor 66 enables the head 20 to be oscillated in a γ direction around the X axis and to be positioned at an arbitrary position. The motor 68 enables the head 20 to be oscillated in an a direction around the Z axis, and to be positioned at an arbitrary position.

As described above, the substrate 48 can be moved and positioned in the Y direction, and can be oscillated and positioned in the θz direction. Furthermore, the head 20 can be moved and positioned in the X and Z directions and can be oscillated and positioned in the α, β and γ directions. Accordingly, the droplet discharging device 10 of the present embodiment is designed to precisely control a relative position and posture between an ink discharging surface 20P of the head 20 and the substrate 48 on the table 46.

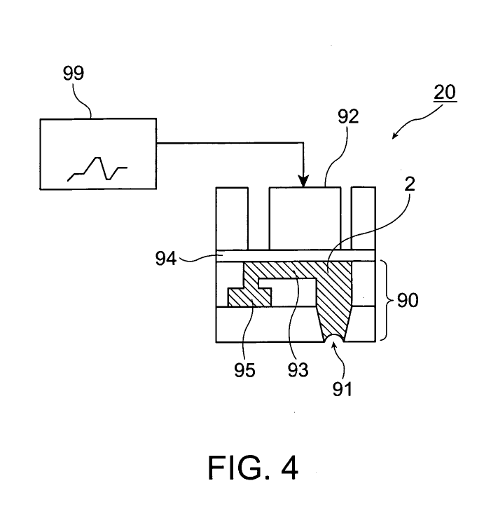

Now, a structural example of the head 20 is described referring to FIG. 4. FIG. 4 is a side cross-sectional view of an ink jet head. The head 20 discharges a liquid material 2 from nozzles 91 in a droplet discharging method. As the droplet discharging method, various technologies are applicable, including a piezo system in which the liquid material is discharged using a piezo actuator as a piezoelectric body element, a method in which by bubbles generated by heating the liquid material, the liquid material is discharged, or the like. In these technologies, the piezo system has an advantage that the composition of the material or the like is not affected because the liquid material is not heated. Therefore, the above-mentioned piezo system can be employed for the head 20 in FIG. 4.

In a head body 90 of the head 20, a reservoir 95 and a plurality of ink chambers 93 branched from the reservoir 95 are formed. The reservoir 95 is a flow path for supplying the liquid material 2 to the respective ink chambers 93. Furthermore, a nozzle plate constituting the ink discharging surface is attached to the lower end surface of the head body 90. In the nozzle plate, the plurality of nozzles 91 discharging the liquid material 2 are opened corresponding to the respective ink chambers 93. In addition, ink flow paths are formed from the respective ink chambers 93 to the corresponding nozzles 91. On the other hand, a vibrating plate 94 can be attached to an upper end surface of the head body 90. The vibrating plate 94 constitutes a wall surface of the respective ink chambers 93. Outside of the vibrating plate 94, there are provided piezo actuators 92 corresponding the respective ink chambers 93. Each of the piezo actuators 92 holds a piezoelectric material such as quartz crystal between a pair of electrodes (not shown). The pair of electrodes is coupled to a drive circuit 99.

When voltage is applied to the piezo actuators 92 from the drive circuit 99, the piezo actuators 92 are deformed expansively or contractively. When the piezo actuators 92 are deformed contractively, pressure of the ink chambers 93 is decreased, so that the liquid material 2 flows into the ink chambers 93 from the reservoir 95. Furthermore, when the piezo actuators 92 are deformed expansively, the pressure of the ink chambers 93 is increased, so that the liquid material 2 is discharged from the nozzles 91. By changing the applied voltage, a deformation amount of the piezo actuators 92 can be controlled. Furthermore, by changing frequency of the applied voltage, a deformation speed of the piezo actuators 92 can be controlled. In other words, by controlling the applied voltage to the piezo actuators 92, discharging conditions of the liquid material 2 can be controlled.

On the other hand, the droplet discharging device shown in FIG. 3 can include the capping unit 22 and the cleaning unit 24. The capping unit 22 caps the ink discharging surface 20P during standby of the droplet discharging device 10 in order to prevent the ink discharging surface 20 P in the head 20 from being dried. Furthermore, the cleaning unit 24 sucks the inside of the nozzles in order to remove clogging of the nozzles in the head 20. The cleaning unit 24 can wipe the ink discharging surface 20P since the dirt of the ink discharging surface 20P in the head 20 is removed.

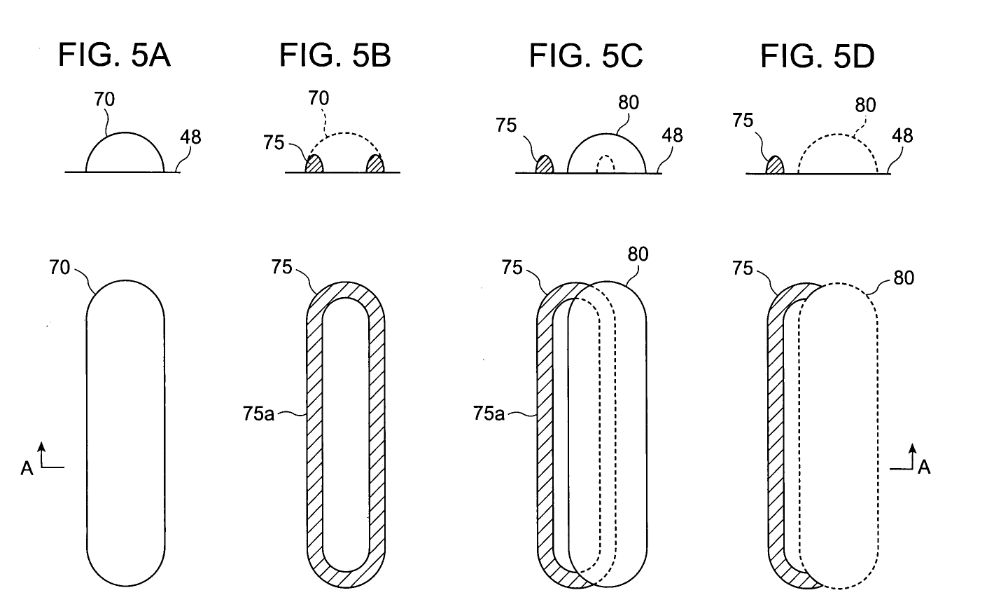

Next, a second exemplary embodiment of the invention is described using FIG. 5. In a film forming method according to the second embodiment, firstly as shown in FIG. 5A, the first droplet 70 is discharged on the substrate 48 (droplet discharging step). Next, as shown in FIG. 5B, in the peripheral part of the first droplet 70, the first dry film 75 is formed (pinning step). Then, as shown in FIG. 5C, on the substrate 48, a second droplet 80 is arranged and a part of the first dry film 75 is redispersed (redispersion step). Next, as shown in FIG. 5D, a part of the first dry film 75 is removed together with the second droplet 80 (droplet removal step). Thereby, an electric wiring pattern composed of a remaining part of the first dry film 75 can be obtained. The respective steps mentioned above are sequentially described below, however, detailed description of parts having similar structures to those of the first embodiment is omitted.

In the second embodiment, the droplet discharging step and the pinning step are performed similarly to the first embodiment.

Next, the redispersion step is performed. In the redispersion step, as shown in FIG. 5C, the second droplet 80 is arranged on the substrate 48 and the first dry film 75 is redispersed. The second droplet 80 is composed of a dispersion medium capable of dispersing the forming material of the first dry film 75. The film forming method of the second embodiment does not have the repinning step forming the second dry film from the second droplet. Therefore, with regard to the second droplet 80, the conductive fine particles as the forming material of the second dry film, or the like do not need to be dispersed. Accordingly, the second droplet 80 is desirably composed of only the above-mentioned dispersion medium. This dispersion medium may be the same liquid material as the dispersion medium of the first droplet, or may be different liquid material.

In the case where only a predetermined part of the above-mentioned first dry film 75 is used as an electric wiring pattern, a part of the first dry film 75 needs to be removed. Therefore, the second droplet 80 is arranged so as to include the removal part of the first dry film 75. The shape of the second droplet 80 is not limited to stripe as shown in FIG. 5C, but may be an arbitrary shape including the removal part of the first dry film 75. Furthermore, it is preferable that after the utilization part of the first dry film 75 is heat-treated, the second droplet 80 is arranged. In addition, after the utilization part of the first dry film 75 is heat-treated, the second droplet 80 may be arranged so as to include the entire first dry film 75. In this case, the utilization part of the first dry film 75 is not redispersed in the second droplet 80 but only the other part is redispersed. According to this structure, it is unnecessary to assure position precision of the second droplet 80, and the redispersion step can be simplified.

Then, as shown in FIG. 5D, the second droplet 80 is removed (droplet removal step). The removal of the second droplet 80 can be performed by a method of inclining the substrate 48, a method of spraying a gas on the surface of the substrate 48, or the like. Thereby, the first dry film 75 redispersed in the second droplet 80 is removed together with the second droplet 80.

As described above, the fine electric wiring pattern composed of the remaining part of the first dry film 75 is formed.

In the above-mentioned film forming method of the second exemplary embodiment, the removal part of the first dry film 75 is redispersed in the second droplet 80 to be removed. According to this structure, the utilization part of the first dry film 75 can be left precisely, and the other part can be removed precisely. Accordingly, a extremely fine electric wiring pattern can be formed.

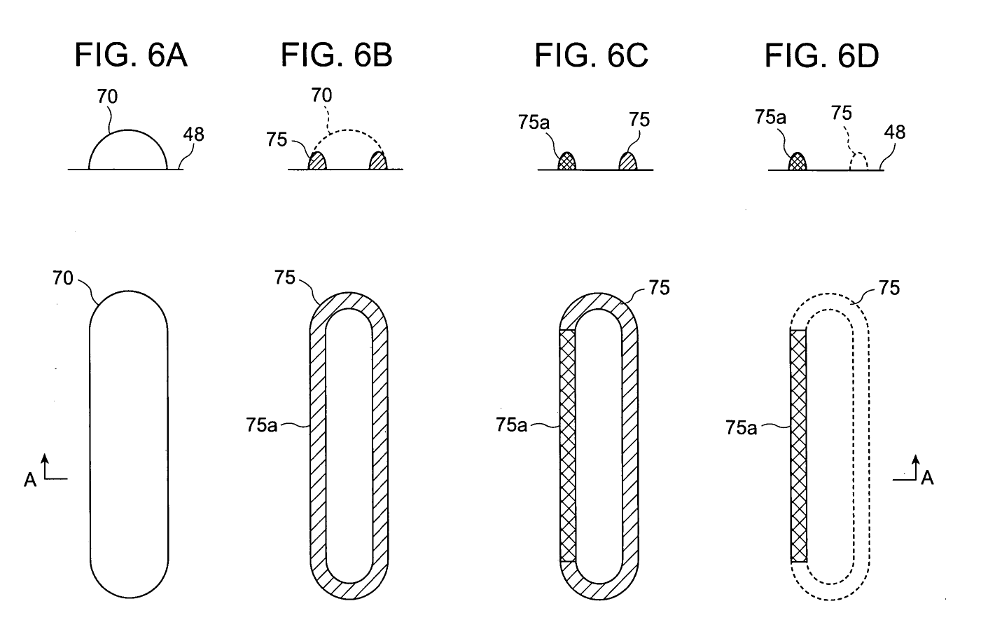

Next, a third exemplary embodiment of the invention is described using FIG. 6. In a film forming method of the third embodiment, firstly as shown in FIG. 6A, the first droplet 70 is discharged on the substrate 48 (droplet discharging step). Next, as shown in FIG. 6B, in the peripheral part of the first droplet 70, the first dry film 75 is formed (pinning step). Then, as shown in FIG. 6C, the utilization part of the first dry film 75 (the linear part 75a) is heat-treated (heat treatment step). Next, as shown in FIG. 6D, the entire substrate 48 is immersed in the dispersion medium and a part of the first dry film 75 is redispersed (redispersion step). Thereby, an electric wiring pattern composed of the remaining part of the first dry film 75 (the linear part 75a) can be obtained. The respective steps mentioned above are sequentially described below, however, detailed description of parts having similar structures to those of the first embodiment is omitted.

In the third exemplary embodiment, the droplet discharging step and the pinning step are performed similarly to the first exemplary embodiment.

In the third exemplary embodiment, the heat treatment step is subsequently performed. In the heat treatment step, as shown in FIG. 6C, the linear part 75a as the utilization part of the first dry film 75 is heat-treated. In order to precisely subject only the linear part 75a to the heat treatment, the heat treatment is desirably performed by laser irradiation or the like. Then, the protective layer on the surface of the fine particle in the linear part 75a is decomposed and the fine wiring is calcinated. Furthermore, the remaining dispersion medium in the linear part 75a is removed. Thereby, the linear part 75a can be prevented from being redispersed.

Next, as shown in FIG. 6D, the entire substrate 48 is immersed in the dispersion medium to redisperse the first dry film 75 (redispersion step). Firstly, a dispersion medium in which the component material of the first dry film 75 can be dispersed is filled in a vessel of a size capable of immersing the substrate 48. This dispersion medium may be the same liquid material as the dispersion medium of the first droplet, or different liquid material. The substrate 48 is immersed in the dispersion medium. Then, a part other than the linear part 75a of the first dry film 75 is redispersed in the dispersion medium, and thus only the heat-treated linear part 75a remains on the substrate 48.

As described above, a fine electric wiring pattern composed of the linear part 75a of the first dry film 75 is formed.

In the above-mentioned film forming method of the third exemplary embodiment, after the utilization part of the first dry film 75 is heat-treated, the substrate 48 is immersed in the dispersion medium and the other part is redispersed. This structure allows the utilization part of the first dry film to be left precisely and the other part to be removed precisely. Particularly, in the third exemplary embodiment, since such patterning of the first dry film 75 can be easily performed, manufacturing cost can be reduced.

In the case where the part of the first dry film to be removed is mechanically removed, the heat treatment step of the part to be left can be omitted. In this case, the manufacturing cost can be further reduced.

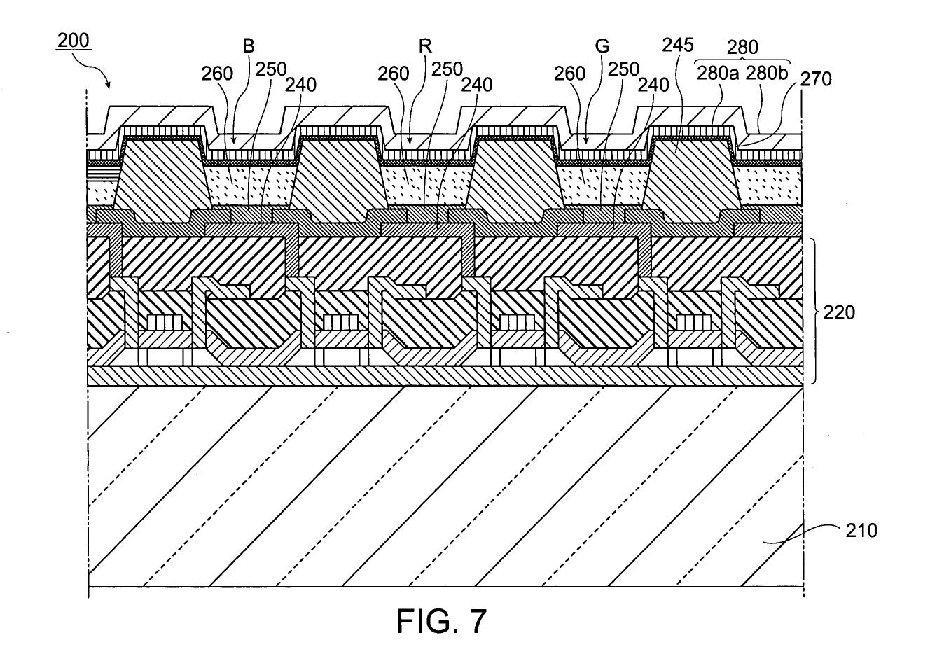

Next, an organic EL device, which is an example of an electro-optic device manufactured using the film forming methods of the respective embodiments is described, using FIG. 7.

An organic EL device 200 can include a plurality of pixel regions R, G and B arranged in matrix. On a surface of a substrate 210, a circuit part 220 driving the respective pixel regions is formed, and on the surface of the circuit part 220, a plurality of pixel electrodes 240 are formed in matrix. Around each of the pixel electrodes 240, a bank 245 composed of an electrical insulating material is formed. On a surface of the pixel electrode 240 functioning as a anode, a hole injection layer 250 and a light emitting layer 260 are sequentially formed. Furthermore, on the entire surface of the light emitting layer 260 and the bank 245, an electron injection layer 270 and a common cathode 280 are formed. A sealing substrate (not shown) is stuck to an end part of the substrate 210 to seal the whole tightly.

In addition, by using the film forming methods of the respective embodiments, patterning of the respective functional layers composing the above-mentioned organic EL device 200 can be performed. By having such extremely fine functional layers, the small-size organic EL device excellent in display quality can be provided.

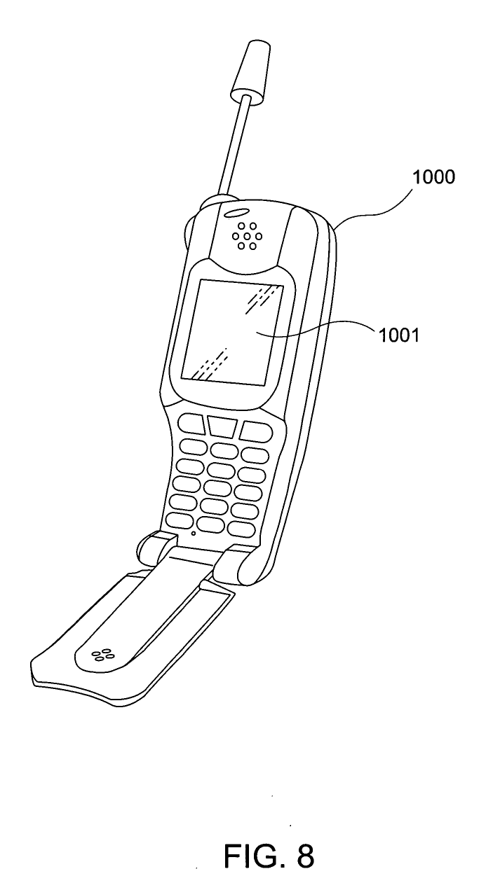

Next, electronic equipment formed using the film forming methods of the respective embodiments is described using FIG. 8. FIG. 8 is a perspective view of a cellular phone. In FIG. 8, reference numeral 1000 denotes a cellular phone body, reference numeral 1001 denotes a display part. This cellular phone 1000 can include the display part 1001 formed using the film forming methods of the respective exemplary embodiments. Accordingly, the small-size cellular phone 1000 excellent in display quality can be provided at low cost.

It should be understood that the technical scope of the invention is not limited to the above-mentioned exemplary embodiments, but various modifications of the above-mentioned exemplary embodiments can be included within the scope not departing from the gist of the invention.

Specifically, the specific materials and structures described in the respective embodiments are only examples, and can be modified as necessary. For example, in the foregoing, the cases where the film is formed using the dispersion liquid in which the dispersoid is dispersed in the dispersion medium are described as an example, but the present invention can be applied to a case where a film is formed using a solution in which a solute is dissolved in a solvent. Furthermore, in the foregoing, the cases where the electric wiring pattern is formed are described as an example, but the present invention can be applied to a case where other patterns are formed.

Two kinds of liquid materials were manufactured to conduct an experiment with regard to redispersibility of the dry film.

Ag fine particles (with a calcination temperature of about 300° C.) were employed as a dispersoid and tetradecan (with a boiling point of about 251° C.) was employed as a dispersion medium to manufacture a liquid material A. Ag fine particles (with a calcinations temperature of about 125° C.) were employed as a dispersoid and water (with a boiling point of about 100° C.) was employed as a dispersion medium to manufacture a liquid material B. Then, each of the liquid materials was discharged on a substrate to form a first droplet and to form a first dry film in a peripheral part of the droplet (pinning step). Further, on the dry film, each of the liquid materials is discharged to arrange a second droplet and the redispersiblity of the dry film is examined.

As a result, in the case of the liquid material A, the first dry film was redispersed in the second droplet, while in the case of the liquid material B, the first dry film was not redispersed. It is considered that this was because in the liquid material B, the protective layer of the Ag fine particle was thin, and thus adhesion between the Ag fine particles in the first dry film was high, which did not cause redispersion in the second droplet. In contrast, it is considered that in the liquid material A, since the boiling point of the dispersion medium was high, the dispersion medium remained in the first dry film, and thus adhesion between the Ag fine particles was low, which caused the redispersion in the second droplet.

While this invention has been described in conjunction with the specific embodiments thereof, it is evident that many alternatives, modifications, and variations will be apparent to those skilled in the art. Accordingly, preferred embodiments of the invention as set forth herein are intended to be illustrative, not limiting. There are changes that may be made without departing from the spirit and scope of the invention.

1. A film forming method, comprising:
arranging a first droplet on a substrate;
forming a first dry film in a peripheral portion of the first droplet; and
removing a portion of the first dry film and forming a desired film pattern by a remaining portion of the first dry film.

2. A film forming method, comprising:
arranging a first droplet on a substrate;
forming a first dry film in a peripheral portion of the first droplet;
arranging a second droplet so as to include a portion of the first dry film and redispersing or redissolving the portion of the first dry film; and
removing the second droplet and forming a desired film pattern by a remaining portion of the first dry film.

3. A film forming method, comprising:
arranging a first droplet on a substrate;
forming a first dry film in a peripheral portion of the first droplet;
arranging a second droplet so as to include a portion of the first dry film and redispersing or redissolving the portion of the first dry film; and
forming a second dry film in a peripheral portion of the second droplet.

4. The film forming method according to claim 1, after forming the first dry film, a region corresponding to the remaining portion of the first dry film being heat-treated.

5. The film forming method according to claim 1, before forming the first dry film, a component material of the first dry film and the substrate being charged to a same charge.

6. The film forming method according to claim 2, the second droplet being composed of only a dispersion medium or a solvent of a component material of the first dry film.

7. The film forming method according to claim 3, a concentration of a component material of the second dry film in the second droplet being set so as to be a desired concentration in a state that the part of the first dry film is redispersed or redissolved.

8. A device manufacturing method, using the film forming method according to claim 1, a film pattern being formed on the substrate.

9. A device manufacturing method, using the film forming method according to claim 1, electric wiring being formed on the substrate.

10. An electro-optic device comprising a device manufactured using the device manufacturing method of claim 8.
